(19) United States
(12) Patent Application Publication
(10) Pub. No.: US 2025/0135508 A1
(43) Pub. Date: May 1, 2025

(54) APPARATUS FOR TREATING A SUBSTRATE AND METHOD FOR TREATING A SUBSTRATE

(71) Applicant: SEMES CO., LTD., Cheonan-si (KR)

(72) Inventors: Jin Kyu KIM, Suwon-si (KR); Hyeong Soo PARK, Yongin-si (KR); Gu Won SEON, Seoul (KR)

(73) Assignee: SEMES CO., LTD., Cheonan-si (KR)

(21) Appl. No.: 18/927,168

(22) Filed: Oct. 25, 2024

(30) Foreign Application Priority Data
Oct. 25, 2023 (KR) 10-2023-0143626

(51) Int. Cl. B08B 3/02; B08B 3/08; B08B 5/02; B08B 11/02

(52) U.S. Cl. CPC B08B 3/024; B08B 3/08; B08B 5/02; B08B 11/02

(57) ABSTRACT

Disclosed is an apparatus for treating a substrate, the apparatus including: a spin chuck for supporting a substrate and rotatable; a nozzle unit for supplying a cleaning solution and drying gas onto the substrate supported by the spin chuck; and a controller for controlling the nozzle unit, in which the nozzle unit includes: a head; a plurality of cleaning nozzles provided on the head and for discharging the cleaning solution; a plurality of drying nozzles provided on the head and for discharging the drying gas; and a driver for moving the head from a first position to a second position, when the head is in the second position, an impact point of the cleaning solution discharged from the plurality of cleaning nozzles onto the substrate is at a location farther from a center of the substrate than an impact point of the cleaning solution when the head is in the first position, the cleaning solution is discharged simultaneously from the plurality of cleaning nozzles, the impact points of the cleaning solution are located at different distances from the center of the substrate, when the drying gas is discharged simultaneously from the plurality of drying nozzles, the impact points of the drying gas are located at different distances from the center of the substrate, and when the cleaning solution and the drying gas are discharged simultaneously, the impact point of the cleaning solution is located farther from the center of the substrate than the impact point of the drying gas.

### CROSS-REFERENCE TO RELATED APPLICATIONS

This application claims priority to and the benefit of Korean Patent Application No. 10-2023-0143626 filed in the Korean Intellectual Property Office on Oct. 25, 2023, the entire contents of which are incorporated herein by reference.

### TECHNICAL FIELD

The present invention relates to an apparatus and method of treating a substrate, and more particularly to an apparatus and method of treating a substrate by supplying a cleaning solution to a substrate.

### BACKGROUND ART

To manufacture semiconductor devices or flat display panels, various processes, such as deposition, photography, etching, and cleaning, are performed. Among these processes, the photography process includes an application process in which a photosensitive liquid, such as a photoresist, is applied to a surface of a substrate to form a film, an exposure process in which a circuit pattern is transferred to the film formed on the substrate, and a development process in which the film formed on the substrate is selectively removed from the exposed region or an opposite region of the exposed region. Further, a heat treatment process is performed before and after the application process, the exposure process, and the development process.

In the development process, a developer is supplied to the substrate to selectively dissolve a resist film on the substrate, and then a cleaning solution and drying gas are discharged onto the rotating substrate to clean and dry the surface of the substrate.

When the cleaning solution and drying gas are supplied to the rotating substrate, increasing the amount of cleaning solution and drying gas discharged from the nozzle to increase the throughput may damage the substrate or leave particles on the substrate due to the increased hydraulic pressure.

### SUMMARY OF THE INVENTION

The present invention has been made in an effort to provide a substrate treating apparatus capable of efficiently treating a substrate.

The present invention has been made in an effort to provide a substrate treating apparatus capable of minimizing damage to a substrate or particles left on the substrate due to a cleaning solution or drying gas discharged onto the substrate.

The present invention has been made in an effort to provide a substrate treating apparatus capable of rapidly cleaning and drying a substrate.

The object of the present invention is not limited thereto, and other objects not mentioned will be clearly understood by those of ordinary skill in the art from the following description.

An exemplary embodiment of the present invention provides an apparatus for treating a substrate, the apparatus including: a spin chuck for supporting a substrate and rotatable; a nozzle unit for supplying a cleaning solution and drying gas onto the substrate supported by the spin chuck; and a controller for controlling the nozzle unit, in which the nozzle unit includes: a head; a plurality of cleaning nozzles provided on the head and for discharging the cleaning solution; a plurality of drying nozzles provided on the head and for discharging the drying gas; and a driver for moving the head from a first position to a second position, when the head is in the second position, an impact point of the cleaning solution discharged from the plurality of cleaning nozzles onto the substrate is at a location farther from a center of the substrate than an impact point of the cleaning solution when the head is in the first position, the cleaning solution is discharged simultaneously from the plurality of cleaning nozzles, the impact points of the cleaning solution are located at different distances from the center of the substrate, when the drying gas is discharged simultaneously from the plurality of drying nozzles, the impact points of the drying gas are located at different distances from the center of the substrate, and when the cleaning solution and the drying gas are discharged simultaneously, the impact point of the cleaning solution is located farther from the center of the substrate than the impact point of the drying gas.

According to the exemplary embodiment of the present invention, when the head is in the first position, the cleaning solution may be discharged into a center region of the substrate, and when the head is in the second position, the drying gas may be discharged to an edge region of the substrate.

According to the exemplary embodiment of the present invention, the driver may be provided to move the head in a straight line between the first position and the second position along a radial direction of the substrate supported on the spin chuck, and the impact points of the cleaning solution discharged from the plurality of cleaning nozzles onto the substrate may be located in a straight line.

According to the exemplary embodiment of the present invention, the driver may be provided to move the head in a straight line between the first position and the second position along a radial direction of the substrate supported on the spin chuck, and the impact points of the drying gas discharged from the plurality of drying nozzles onto the substrate may be located in a straight line.

According to the exemplary embodiment of the present invention, the driver may be provided to move the head in a straight line between the first position and the second position along a radial direction of the substrate supported on the spin chuck, and the impact points of the cleaning solution and the drying gas discharged onto the substrate from the plurality of cleaning nozzles and the plurality of drying nozzles may be located in a straight line.

According to the exemplary embodiment of the present invention, when viewed from above, the plurality of cleaning nozzles may be arranged in a direction parallel to a straight line connecting the first position and the second position.

According to the exemplary embodiment of the present invention, when viewed from above, the plurality of drying nozzles may be arranged in a direction perpendicular to a straight line connecting the first position and the second position.

According to the exemplary embodiment of the present invention, the controller may control the cleaning nozzles such that the total amount of cleaning solution discharged from the plurality of cleaning nozzles decreases as the head moves from the first position to the second position.

According to the exemplary embodiment of the present invention, the controller may control the number of the cleaning nozzles discharging the cleaning solution to decrease as the head moves from the first position to the second position.

According to the exemplary embodiment of the present invention, the controller may control the plurality of cleaning nozzles to sequentially stop discharging the cleaning solution starting with the cleaning nozzle of which an impact point of the cleaning solution discharged onto the substrate is farthest from the center of the substrate among the plurality of cleaning nozzles as the head moves from the first position to the second position.

According to the exemplary embodiment of the present invention, the controller may control the drying nozzles such that the total amount of the drying gas discharged from the plurality of drying nozzles increases as the head moves from the first position to the second position.

According to the exemplary embodiment of the present invention, the controller may control the number of the drying nozzles discharging the drying gas to increase as the head moves from the first position to the second position.

According to the exemplary embodiment of the present invention, the controller may control the plurality of drying nozzles to sequentially initiate discharging the drying gas starting with the drying nozzle of which an impact point of the drying gas discharged onto the substrate is the center of the substrate or is closest to the center of the substrate among the plurality of drying nozzles as the head moves from the first position to the second position.

Another exemplary embodiment of the present invention provides a method of treating a substrate by using the foregoing apparatus for treating the substrate, the method including: discharging the cleaning solution and the drying gas from the plurality of cleaning nozzles and the plurality of drying nozzles while moving the head from the first position to the second position, in which the total amount of the cleaning solution discharged from the plurality of cleaning nozzles is gradually reduced, and the total amount of the drying gas discharged from the plurality of drying nozzles is gradually increased.

According to the exemplary embodiment of the present invention, the plurality of cleaning nozzles may sequentially stop the discharging of the cleaning solution starting with the cleaning nozzle of which an impact point of the cleaning solution discharged onto the substrate is farthest from the center of the substrate as the head moves from the first position to the second position.

According to the exemplary embodiment of the present invention, the plurality of drying nozzles may sequentially initiate the discharging of the drying gas starting with the cleaning nozzle of which an impact point of the drying gas discharged onto the substrate is the center of the substrate or is closest to the center of the substrate as the head moves from the first position to the second position.

Still another exemplary embodiment of the present invention provides an apparatus for treating a substrate, the apparatus including: a chamber providing a treatment space therein; a spin chuck for supporting a substrate within the treatment space and rotatable; a nozzle unit for supplying a cleaning solution and drying gas onto the substrate supported by the spin chuck; and a controller for controlling the nozzle unit, in which the nozzle unit may include: a head; a plurality of cleaning nozzles provided on the head and for discharging the cleaning solution; a plurality of drying nozzles provided on the head and discharging the drying gas; and a driver for moving the head in a straight line from a first position to a second position, when the head is in the second position, an impact point of the cleaning solution discharged from the plurality of cleaning nozzles onto the substrate is at a location farther from a center of the substrate than an impact point of the cleaning solution when the head is in the first position, when the cleaning solution is discharged simultaneously from the plurality of cleaning nozzles, the impact points of the cleaning solution are located at different distances from the center of the substrate, when the drying gas is discharged simultaneously from the plurality of drying nozzles, the impact points of the drying gas are located at different distances from the center of the substrate, and when the cleaning solution and the drying gas are discharged simultaneously, the impact point of the cleaning solution is located farther from the center of the substrate than the impact point of the drying gas, and the impact points of the cleaning solution and the drying gas discharged onto the substrate from the plurality of cleaning nozzles and the plurality of drying nozzles are located in a straight line.

According to the exemplary embodiment of the present invention, the controller may control the cleaning nozzles and the drying nozzles such that the total amount of cleaning solution discharged from the plurality of cleaning nozzles decreases and the total amount of drying gas discharged from the plurality of drying nozzles increases as the head moves from the first position to the second position.

According to the exemplary embodiment of the present invention, the controller may control the plurality of cleaning nozzles to sequentially stop discharging the cleaning solution starting with the cleaning nozzle of which an impact point of the cleaning solution discharged onto the substrate is farthest from the center of the substrate among the plurality of cleaning nozzles as the head moves from the first position to the second position.

According to the exemplary embodiment of the present invention, the controller may control the plurality of drying nozzles to sequentially initiate discharging the drying gas starting with the drying nozzle of which an impact point of the drying gas discharged onto the substrate is the center of the substrate or is closest to the center of the substrate among the plurality of drying nozzles as the head moves from the first position to the second position.

According to the exemplary embodiment of the present invention, substrates may be treated efficiently by freely adjusting the discharge flow rate of cleaning solution and drying gas through a plurality of cleaning nozzles and a plurality of drying nozzles. Further, according to the exemplary embodiment of the present invention, damage to the substrate or residual particles on the substrate due to the cleaning solution or drying gas discharged onto the substrate may be minimized.

Further, according to the exemplary embodiment of the present invention, the nozzle unit may adjust the drying speed of the cleaning solution and the process speed by adjusting the ratio of the total amount of cleaning solution discharged onto the substrate to the total amount of drying gas discharged onto the substrate.

Furthermore, according to the exemplary embodiment of the present invention, the substrate may be dried quickly through the drying gas without relying on drying by rotation of the substrate.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a perspective view schematically illustrating a substrate treating apparatus according to an exemplary embodiment of the present invention.

FIG. 2 is a front view of the substrate treating apparatus of FIG. 1.

FIG. 3 is a top plan view of an applying block in the substrate treating apparatus of FIG. 1.

FIG. 4 is a top plan view of a developing block in the substrate treating apparatus of FIG. 1.

FIG. 5 is a diagram illustrating one example of a hand of a transfer robot.

FIG. 6 is a top plan view schematically illustrating one example of a heat treating chamber of FIG. 3 or FIG. 4.

FIG. 7 is a front view of the heat treating chamber of FIG. 6.

FIG. 8 is a front view schematically illustrating a liquid treating chamber of FIG. 3 or 4.

FIG. 9 is a perspective view illustrating a head of a nozzle unit according to the exemplary embodiment of the present invention.

FIG. 10 is a top plan view of the head of FIG. 9.

FIGS. 11 to 19 are diagrams schematically illustrating the processes of treating a substrate by using a nozzle unit in the liquid treating chamber of FIG. 8.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be treated. However, the technical spirit of the present invention may be applied to devices used for other types of substrate treatment, in addition to wafers.

Hereinafter, exemplary embodiments of the present invention will be described with reference to the accompanying drawings.

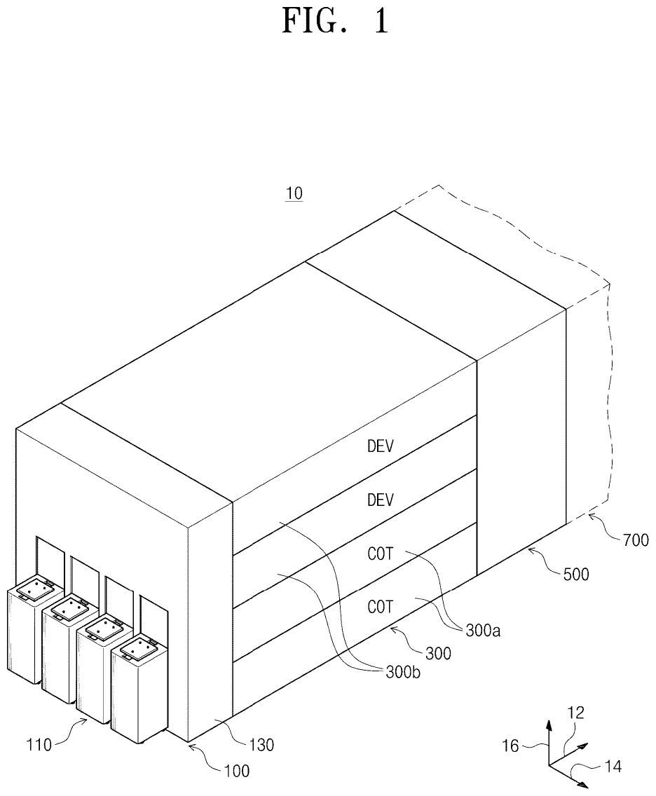

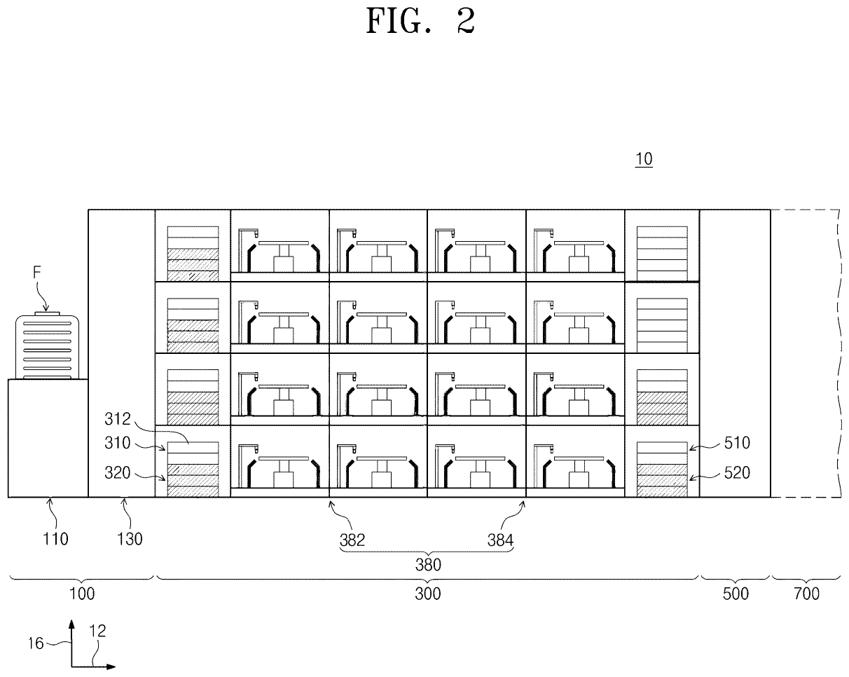

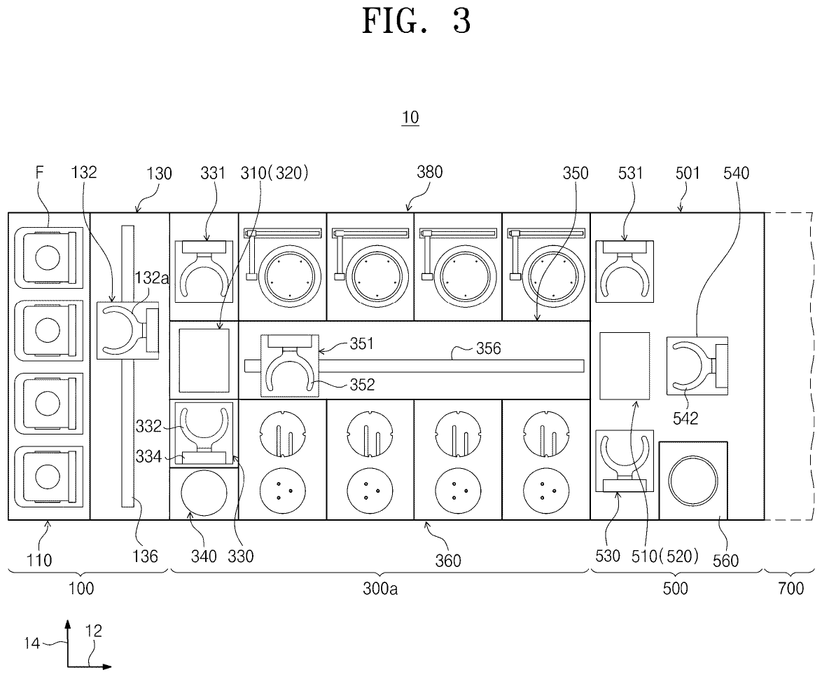

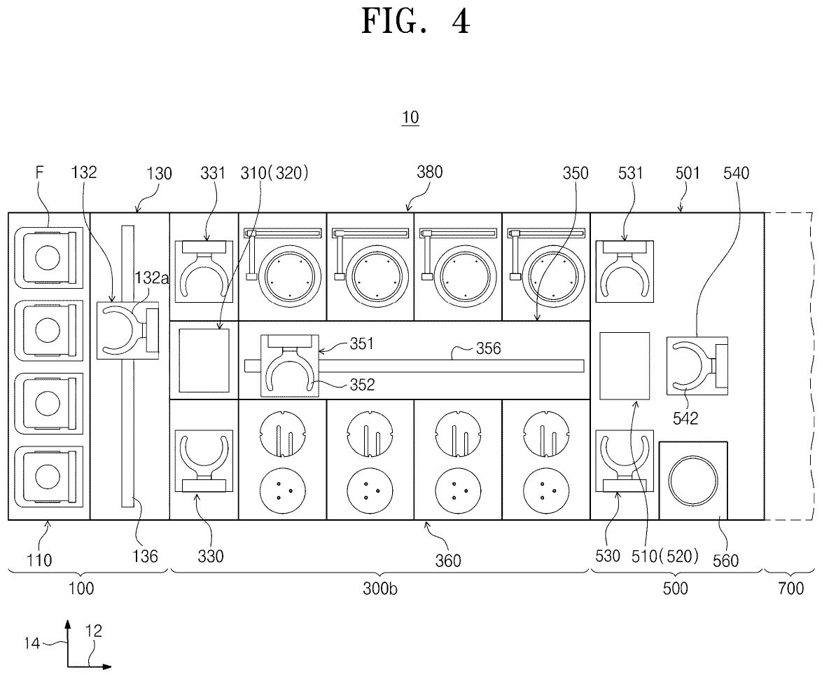

FIG. 1 is a perspective view schematically illustrating a substrate treating apparatus according to an exemplary embodiment of the present invention, and FIG. 2 is a front view of the substrate treating apparatus of FIG. 1. FIG. 3 is a top plan view of an applying block in the substrate treating apparatus of FIG. 1, and FIG. 4 is a top plan view of a developing block in the substrate treating apparatus of FIG. 1.

Referring to FIGS. 1 to 4, a substrate treating apparatus 10 includes an index module 100, a treating module 300, and an interface module 500. According to the exemplary embodiment, the index module 100, the treating module 300, and the interface module 500 are sequentially arranged in a row. Hereinafter, a direction in which the index module 100, the treating module 300, and the interface module 500 are arranged is defined as a first direction 12, a direction perpendicular to the first direction 12 when viewed from above is defined as a second direction 14, and a direction perpendicular to both the first direction 12 and the second direction 14 is defined as a third direction 16.

The index module 100 is provided for transferring a substrate W between a container F in which the substrate W is accommodated and the treating module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the treating module 300 with respect to the index frame 130. A plurality of load ports 110 may be provided, and the plurality of load ports 110 may be disposed along the second direction 14.

In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 so as to be movable along the guide rail 136. The index robot 132 includes a hand 132a on which the substrate W is placed. The hand 132a may be provided to be movable forwardly and backwardly, movable linearly along the third direction, and rotatably movable about the axis of the third direction 16.

The treating module 300 performs an application process and a development process on the substrate W. The treating module 300 includes an applying block 300a and a developing block 300b.

The applying block 300a performs an application process on the substrate W before the exposure process. The developing block 300b performs a development process on the substrate W after the exposure process. A plurality of applying blocks 300a is provided. The plurality of applying blocks 300a may be provided while being stacked on top of each other. A plurality of developing blocks 300b is provided. The plurality of developing blocks 300b may be provided to be stacked with each other. In one example, two applying blocks 300a are provided and two developing blocks 300b are provided. The plurality of applying blocks 300a may be located below the developing blocks 300b.

In one example, the plurality of applying blocks 300a may be provided with structures that are identical to each other. A film applied to the substrate W in each of the plurality of applying blocks 300a may be the same type of film. Optionally, the films applied to the substrate W by each applying block 300a may be different types of films. The film applied to the substrate W includes a photoresist film. The film applied to the substrate W may further include an anti-reflective film. Optionally, the film applied to the substrate W may further include a protective film.

Additionally, the two developing blocks 300b may be provided with the same structures as each other. A developer supplied to the substrate W in the plurality of developing blocks 300b may be the same type of liquid. Optionally, the developer supplied to the substrate W may be different types of developer depending on the developing blocks 300b. For example, a process for removing a light-irradiated region in a region of a register film on the substrate W may be performed in one of the two developing blocks 300b, and a process for removing a non-irradiated region may be performed in the other of the two developing blocks 300b.

Referring to FIG. 3, the applying block 300a includes a buffer unit 310, a cooling unit 320, a hydrophobization chamber 340, a transfer chamber 350, a heat treating chamber 360, and a liquid treating chamber 380.

The buffer unit 310, the cooling unit 320, and the hydrophobization chamber 340 are disposed adjacent to the index module 100. The hydrophobization chamber 340 and the buffer unit 310 may be sequentially disposed along the second direction 14. In addition, the cooling unit 320 and the buffer unit 310 may be provided to be stacked on top of each other in a vertical direction.

The buffer unit 310 includes one or a plurality of buffers 312. When a plurality of buffers 312 is provided, the plurality of buffers 312 may be arranged to be stacked on top of each other. The buffer 312 provides a space for the substrate W to stay when the substrate W is transferred between the index module 100 and the treating module 300. The hydrophobization chamber 340 provides a hydrophobization treatment to the surface of the substrate W. The hydrophobization treatment may be performed prior to performing an application process on the substrate W. The hydrophobization treatment may be accomplished by supplying hydrophobizing gas to the substrate W while heating the substrate W. The cooling unit 320 cools the substrate W. The cooling unit 320 includes one or more cooling plates. When a plurality of cooling plates is provided, the plurality of cooling plates may be arranged to be stacked on top of each other. In one example, the cooling unit 320 may be disposed below the buffer unit 310. The cooling plate may have a flow path through which coolant flows. The substrate W after the hydrophobization treatment may be cooled on the cooling plate.

A transfer mechanism 330 is provided between the hydrophobization chamber 340 and the buffer unit 310 and between the hydrophobization chamber 340 and the cooling unit 320. The transfer mechanism 330 is provided for transferring the substrate W between the buffer unit 310, the hydrophobization chamber 340, and the cooling unit 320.

The transfer mechanism 330 includes a hand 332 on which the substrate W is placed, and the hand 332 may be provided to be movable forwardly and backwardly, rotatable about the third direction 16, and movable along the third direction 16. In one example, the transfer mechanism 330 is moved in the third direction 16 along a guide rail 334. The guide rail 334 extends from an applying block located at the lowest of the applying blocks 300a to a developing block located at the highest of the developing blocks 300b. This allows the transfer mechanism 330 to transfer the substrate W between the blocks 300a and 300b provided on different layers. For example, the transfer mechanism 330 may transfer the substrate W between the applying blocks 300a and 300b provided on different layers. The transfer mechanism 330 may also transfer the substrate W between the applying block 300a and the developing block 300b.

In addition, another transfer unit 331 may be further provided on the opposite side of the side where the hydrophobization chamber 340 is provided with respect to the buffer unit 310. Another transfer unit 331 may be provided to transfer the substrate W between the buffer unit 310 and the cooling unit 320 provided in the same block 300a and 300b. Further, another transfer unit 331 may be provided to transfer the substrate W between the buffer unit 310 and the cooling unit 320 provided in different blocks 300a and 300b.

The transfer chamber 350 is provided so that a longitudinal direction thereof is parallel to the first direction 12. One end of the transfer chamber 350 may be located adjacent to the buffer unit 310 and/or the cooling unit 320. The other end of the transfer chamber 350 may be located adjacent to the interface module 500.

A plurality of heat treating chambers 360 is provided. Some of the heat treating chambers 360 is disposed along the first direction 12. Additionally, some of the heat treating chambers 360 may be stacked along the third direction 16. The heat treating chambers 360 may all be located on one side of the transfer chamber 350.

The liquid treating chamber 380 performs a liquid film formation process to form a liquid film on the substrate W. In one example, the liquid film forming process includes a resist film forming process. The liquid film forming process may include an anti-reflective film forming process. Optionally, the liquid film forming process may further include a protective film forming process. A plurality of liquid treating chambers 380 is provided. The liquid treating chambers 380 may be located on opposite sides of the heat treating chamber 360. For example, all of the liquid treating chambers 380 may be located on the other side of the transfer chamber 350. The liquid treating chambers 380 are arranged side by side along the first direction 12. Optionally, some of the liquid treatment chambers 380 may be stacked along the third direction 16.

In one example, the liquid treating chambers 380 include a front end liquid treating chamber and a rear end liquid treating chamber. The front end liquid treating chamber is disposed relatively close to the index module 100, and the rear end liquid treating chamber is disposed more proximate to the interface module 500.

A first liquid is applied onto the substrate W in the front end liquid treating chamber, and a second liquid is applied to the substrate W in the rear end liquid treating chamber. The first liquid and the second liquid may be different types of liquid. In one example, the first liquid may be a liquid for forming an anti-reflective film and the second liquid may be a liquid for forming a photoresist film. The photoresist film may be formed on a substrate W to which an anti-reflective film has been applied. Optionally, the first liquid may be a liquid for forming a photoresist film, and the second liquid may be a liquid for forming an antireflective film. In this case, the anti-reflective film may be formed on the substrate W on which the photoresist film is formed. Optionally, the first liquid and the second liquid may be the same kind of liquid, and they may both be liquids for forming the photoresist film.

Referring to FIG. 4, the developing block 300b includes a buffer unit 310, a cooling unit 320, a transfer chamber 350, a heat treating chamber 360, and a liquid treating chamber 380. The arrangement of the buffer unit 310, the cooling unit 320, the transfer chamber 350, the heat treating chamber 360, and the liquid treating chamber 380 in the developing block 300b may be the same as the arrangement of the buffer unit 310, the cooling unit 320, the transfer chamber 350, the heat treating chamber 360, and the liquid treating chamber 380 in the applying block 300a. When viewed from above, the buffer unit 310, the cooling unit 320, the transfer chamber 350, the heat treating chamber 360, and the liquid treating chamber 380 in the developing block 300b and the buffer unit 310, the cooling unit 320, the transfer chamber 350, the heat treating chamber 360, and the liquid treating chamber 380 in the applying block 300 may be disposed in overlapping positions.

The heat treating chamber 360 performs a heating process on the substrate W. The heating process includes a post-exposure baking process performed on the substrate W after the exposure process is completed, and a hard baking process performed on the substrate W after the development process is completed.

The liquid treating chamber performs the development process by supplying a developer onto the substrate W and developing the substrate W.

In FIG. 3 or FIG. 4, the transfer chamber 350 is provided with the transfer robot 351. The transfer robot 351 transfers the substrate W between the buffer unit 310, the cooling unit 320, the heat treating chamber 360, the liquid treating chamber 380, and the buffer unit 510 or the cooling unit 520 of the interface module 500. In one example, the transfer robot 351 includes a hand 352 on which the substrate W is placed. The hand 352 may be provided to be movable forwardly and backwardly, rotatable about the third direction 16, and movable along the third direction 16. A guide rail 356, of which a longitudinal direction is parallel to the first direction 12, is provided within the transfer chamber 350, and the transfer robot 351 may be provided to be movable on the guide rail 356.

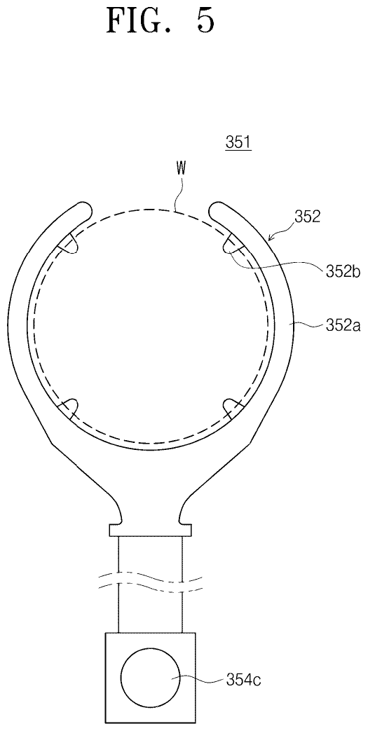

FIG. 5 is a diagram illustrating one example of a hand of the transfer robot. Referring to FIG. 5, the hand 352 includes a base 352a and a support protrusion 352b. The base 352a may have an annular ring shape in which a portion of the circumference is bent. The base 352a has an inner diameter greater than the diameter of the substrate W. The support protrusion 352b extends inwardly from the base 352a. A plurality of support protrusions 352b is provided, and supports an edge region of the substrate W. In one example, support protrusions 352b may be provided in four equally spaced rows.

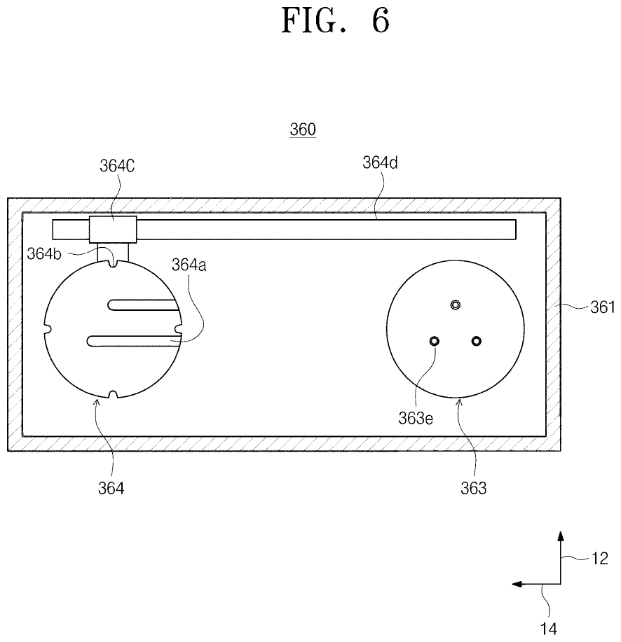

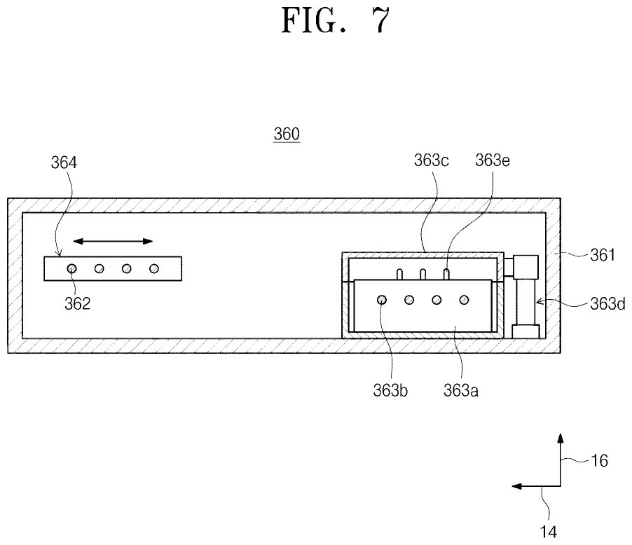

FIG. 6 is a top plan view schematically illustrating an example of the heat treating chamber of FIG. 3 or FIG. 4, and FIG. 7 is a front view of the heat treating chamber of FIG. 6.

Referring to FIGS. 6 and 7, the heat treating chamber 360 includes a housing 361, a heating unit 363, and a transfer plate 364.

The housing 361 is provided in the shape of a generally rectangular parallelepiped. In the sidewall of the housing 361, an entrance opening (not illustrated) is formed through which the substrate W enters and exits. The entrance opening may remain open. Optionally, a door (not illustrated) may be provided to open and close the entrance opening. The heating unit 363 and the transfer plate 364 are provided within the housing 361.

The heating unit 323 includes a heating plate 363a, a cover 363c, and a heater 323b. The heating plate 363a has a generally circular shape when viewed from above. The heating plate 363a has a larger diameter than the substrate W. The heater 363b is installed on the heating plate 363a. The heater 363b may be provided as a heating wire or heating pattern that is heated by the supply of electrical power. The heating plate 363a is provided with a lift pin 363e. The lift pin 363e is provided to be movable in an up and down direction along the third direction 16. The lift pin 363e receives the substrate W from the transfer robot 351 and places the received substrate W on the heating plate 363a, or lifts the substrate W from the heating plate 363a and hands the substrate over to the transfer robot 351. According to the example, three lift pins 363e may be provided. The cover 363c has a space with an open lower portion therein. The cover 363c is located above the heating plate 363a and is moved in a vertical direction by a driver 363d. The space formed by the cover 363c and the heating plate 363a according to the movement of the cover 363c is provided as a heating space for heating the substrate W.

The transfer plate 364 is provided in a substantially disk shape, and has a diameter corresponding to that of the substrate W. A notch 364b is formed at an edge of the transfer plate 364. The notch 364b may have a shape that corresponds to the protrusion 352b formed on the hands 352 of the transfer robot 351 described above. Further, the notches 364b are provided in a number corresponding to the protrusions 352b formed on the hand 352, and are formed at locations corresponding to the protrusions 352b. When the upper and lower positions of the hand 352 and the transfer plate 364 are changed in the position where the hand 352 and the transfer plate 364 are aligned in the vertical direction, the substrate W is transferred between the hand 352 and the transfer plate 364. The transfer plate 364 is mounted on a guide rail 364d, and may be movable along the guide rail 364d by the driver 364c.

A plurality of slit-shaped guide grooves 364a is provided in the transfer plate 364. The guide grooves 364a extend from a distal end of the transfer plate 364 to an interior of the transfer plate 364. The longitudinal direction of the guide groove 364a is provided along the second direction 14, and the guide grooves 364a are spaced apart from each other along the first direction 12. The guide groove 364a prevents the transfer plate 364 and lift pins 363e from interfering with each other when the substrate W is transferred between the transfer plate 364 and the heating unit 363.

The transfer plate 364 is provided with a thermally conductive material. In one example, the transfer plate 364 may be provided from a metal material.

A cooling flow path is formed within the transfer plate 364. The cooling flow path is supplied with cooling water. The substrate W, which has been completely heated in the heating unit 363, may be cooled while being transferred by the transfer plate 364. Also, the substrate W may be cooled on the transfer plate 364 while the transfer plate 364 is stopped for the substrate W to be taken over by the transfer robot 351.

Optionally, a cooling unit may be further provided within the housing 361. In this case, the cooling unit may be arranged in parallel with the heating unit 363. The cooling unit may be provided as a cooling plate having a passage formed therein through which coolant flows. The substrate that has been heated in the heating unit may be returned to the cooling unit for cooling.

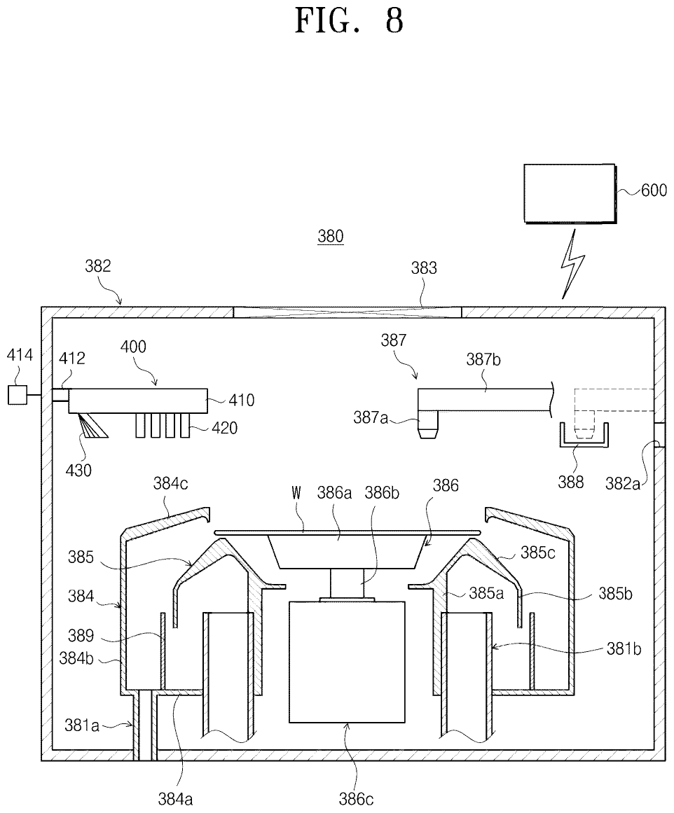

FIG. 8 is a front view schematically illustrating the liquid treating chamber of FIG. 3 or 4.

Referring to FIG. 8, the liquid treating chamber 380 includes a housing 382, an outer cup 384, a spin chuck 386, a treatment solution supply unit 387, a nozzle unit 400, and a controller 600.

The housing 382 is provided in a rectangular cylindrical shape having an inner space. An opening 382a is formed in one side of the housing 382. The opening 382a functions as a passage through which the substrate W enters and exits. A door (not illustrated) is installed in the opening 382a, and the door opens and closes the opening.

An inner space of the housing 382 is provided with the outer cup 384. The outer cup 384 has a treatment space with an open top.

The spin chuck 386 supports the substrate W within the treatment space of the outer cup 384. The support unit 386 includes has a support plate 386a, a rotation shaft 386b, and a driver 386c. The support plate 386a is provided with a circular top surface. The support plate 386a has a diameter smaller than the substrate W. The support plate 386a is provided to support the substrate W by vacuum pressure. The rotation shaft 386b is coupled to the center of the lower surface of the support plate 386a, and the driver 386c is provided on the rotation shaft 386b to provide rotational force to the rotation shaft 386b. The driver 386c may be a motor. Additionally, a lifting driver (not illustrated) may be provided to adjust the relative height of the support plate 386a and the outer cup 384.

The treatment solution supply unit 387 supplies the treatment solution to the substrate W. When the liquid treating chamber 380 is provided in the applying block 300a, the treatment solution may be a liquid for forming a photoresist film, an anti-reflective film, or a protective film. When the liquid treating chamber 380 is provided in the developing block 300b, the treatment solution may be a developer liquid.

In the following, the present invention will be described based on the case where the liquid treating chamber is provided in the developing block, and the treatment solution liquid is a developer as an example. The liquid supply unit 387 includes a nozzle 387a, a nozzle support 387b, and a liquid supply source (not illustrated). The nozzle 387a discharges the treatment solution onto the substrate W. The nozzle 387a is supported on a nozzle support 387b. The nozzle support 387b moves the nozzle 387a between a process position and a standby position. In the process position, the nozzle 387a supplies the treatment solution to the substrate W placed on the support plate 386a, and after completing the supply of the treatment solution, the nozzle 387a waits in the standby position.

The nozzle unit 400 supplies a cleaning solution and drying gas to the substrate W.

The cleaning solution may be pure water (DIW), and the drying gas may be nitrogen gas (N₂).

The nozzle unit 400 includes a head 410, a nozzle arm 412, and a cleaning solution supply source (not shown) and a drying gas supply source (not shown).

The head 410 is supported by the nozzle arm 412. The nozzle arm 412 moves the head 410 by a driving unit 414.

The driving unit 414 moves the head 410 between the process position and the standby position.

The driving unit 414 moves the head 410 from a first position P1 to a second position P2 along the radial direction of the substrate W supported on the spin chuck 386 when the nozzle unit 400 supplies the cleaning solution and the drying gas to the substrate W.

The first position P1 is the position when the head 410 is in the center region of the substrate W when viewed from above, and the second position P2 is the position when the head 410 is in the edge region of the substrate W when viewed from above. The treatment of the substrate by the nozzle unit 400 starts when the head 410 is in the first position P1 and ends when the head 410 is in the second position P2.

Accordingly, impact points of the cleaning solution discharged from the plurality of cleaning nozzles 420 onto the substrate W when the head 410 is in the second position P2 may be located farther from the center of the substrate W than impact points of the cleaning solution when the head 410 is in the first position P1.

The head 410 is provided with a plurality of cleaning nozzles 420 that discharges a cleaning solution, such as pure water, and a plurality of drying nozzles 430 that discharges gas for drying, such as nitrogen gas.

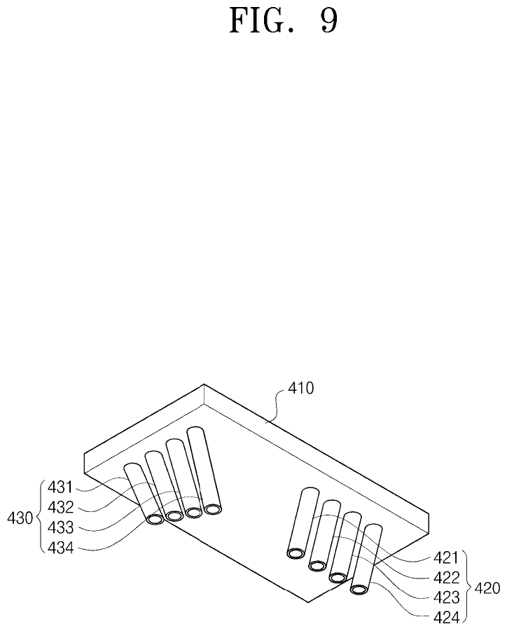

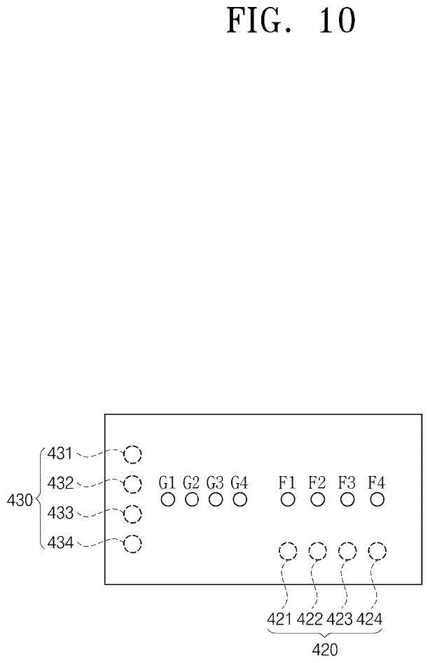

FIG. 9 is a perspective view illustrating a head of a nozzle unit according to the exemplary embodiment of the present invention. Further, FIG. 10 is a top plan view of the head of FIG. 9.

Referring to FIGS. 9 and 10, the plurality of cleaning nozzles 420 provided on the head 410 are arranged in a direction parallel to a straight line connecting the first position P1 and the second position P2. For example, the head 410 may be provided with a first cleaning nozzle 421, a second cleaning nozzle 422, a third cleaning nozzle 423, and a fourth cleaning nozzle 424.

The first to fourth cleaning nozzles 421, 422, 423, and 424 are arranged in a direction parallel to a straight line connecting the first position P1 and the second position P2.

Each of the first to fourth cleaning nozzles 421, 422, 423, and 424 may be arranged with an inclined outlet to discharge the cleaning solution to the top surface of the substrate W in an inclined direction. The first to fourth cleaning nozzles 421, 422, 423, and 424 are spaced apart so that the cleaning solution discharged by each of the first to fourth cleaning nozzles 421, 422, 423, and 424 does not overlap each other and does not scatter. Thus, when the cleaning solution is discharged simultaneously from the first to fourth cleaning nozzles 421, 422, 423, and 424, the impact points of the cleaning solution are located at different distances from the center of the substrate.

The impact points of the cleaning solution discharged by each of the first to fourth cleaning nozzles 421, 422, 423, and 424 may be located in a straight line. For example, when the impact points of the cleaning solution discharged by each of the first to fourth cleaning nozzles 421, 422, 423, and 424 are referred to as first to fourth impact points F1, F2, F3, and F4, the first to fourth impact points F1, F2, F3, and F4 are in a straight line.

The plurality of drying nozzles 430 provided on the head 410 are arranged in a direction perpendicular to the straight line connecting the first position P1 and the second position P2 when viewed from above.

For example, four drying nozzles may be provided, such as a first drying nozzle 431, a second drying nozzle 432, a third drying nozzle 433, and a fourth drying nozzle 434.

The first to fourth drying nozzles 431, 432, 433, and 434 are arranged in a direction perpendicular to the straight line connecting the first position P1 and the second position P2.

The first to fourth drying nozzles 431, 432, 433, and 434 may be arranged with inclined outlets to discharge drying gas to the top surface of the substrate W in an inclined direction. The first to fourth drying nozzles 431, 432, 433, and 434 are spaced apart so that the drying gas discharged by each of first to fourth drying nozzles 431, 432, 433, and 434 does not overlap each other and does not scatter. Thus, when the drying gas is discharged simultaneously from the first to fourth drying nozzles 431, 432, 433, and 434, impact points of the drying gas are located at different distances from the center of the substrate.

When the impact points of the drying gas discharged by each of the first to fourth drying nozzles 431, 432, 433, and 434 are referred to as first to fourth impact points G1, G2, G3, and G4, the first to fourth impact points G1, G2, G3, and G4 are in a straight line.

The impact point described above is the center of the discharge area on the substrate W when the cleaning solution or drying gas discharged from each of the first to fourth cleaning nozzles 421, 422, 423, and 424 or the first to fourth drying nozzles 431, 432, 433, and 434 is discharged onto the surface of the substrate W.

As shown in FIG. 10, the impact points F1, F2, F3, and F4 of the cleaning solution and the impact points G1, G2, G3, and G4 of the drying gas are located in a straight line.

On the top wall of the housing 382, a fan filter unit 383 is disposed to supply a downward airflow to the inner space. The fan filter unit 383 includes a fan that introduces air from the outside into the inner space and a filter that filters the air from the outside.

The outer cup 384 includes a bottom wall 384a, a sidewall 384b, and a top wall 384c. The inner portion of the outer cup 384 is provided as the inner space described above. The inner space H includes a treatment space at the top and an exhaust space at the bottom.

The bottom wall 384a is provided in a circular shape and has an opening in the center. The sidewall 384b extends upwardly from the outer end of the bottom wall 384a. The sidewall 384b is provided in a ring shape and is provided vertical to the bottom wall 384a. In one example, the sidewall 384b extends to a height equal to the top surface of the support plate 386a, or extends to a height slightly lower than the top surface of the support plate 386a. The top wall 384c has a ring shape, with an opening in the center. The top wall 384c is provided with an upward slope from the top end of the sidewall 384b toward the center axis of the outer cup 384.

The guide cup 385 is located on the inner side of the outer cup 384. The guide cup 385 has an inner wall 385a, an outer wall 385b, and a top wall 385c. The inner wall 385a has a through-hole that is perforated in the vertical direction. The inner wall 385a is arranged to surround the driver 386c. The inner wall 385a minimizes the exposure of the driver 386c to the airflow 84 in the treatment space. The rotation shaft 386b and/or the driver 386c of the spin chuck 386 extend in the vertical direction through the through-hole. The outer wall 385b is spaced apart from the inner wall 385a and is disposed to surround the inner wall 385a. The outer wall 385b is spaced apart from the sidewall 384b of the outer cup 384. The inner wall 385a is spaced upwardly from the bottom wall 384a of the outer cup 384. The top wall 385c connects the upper end of the outer wall 385b with the upper end of the inner wall 385a. The top wall 385c has a ring shape and is disposed to surround the support plate 386a. In one example, the top wall 385c has an upwardly convex shape.

The space below the support plate 386a in the treatment space may be provided as an exhaust space. In one example, the exhaust space may be defined by the guide cup 385. The space surrounded by the outer wall 385b, the top wall 385c, and the inner wall 385a of the guide cup 385 and/or the space below the space may be provided as the exhaust space.

The outer cup 384 may be provided with a gas-liquid separation plate 389. The gas-liquid separation plate 389 may be provided to extend upwardly from the bottom wall 384a of the outer cup 384. The gas-liquid separation plate 1230 may be provided in a ring shape. The gas-liquid separation plate 389 may be located between the sidewall 384b of the outer cup 384 and the outer wall 385b of the guide cup 385 when viewed from above. The top end of the gas-liquid separation plate 389 may be located lower than the bottom end of the outer wall 385b of the guide cup 385.

The bottom wall 384a of the outer cup 384 is connected to an outlet pipe 381a for discharging the treatment solution and an exhaust pipe 381b. The discharge pipe 381a may be connected to the outer cup 384 on the outer side of the gas-liquid separation plate 389. The exhaust pipe 381b may be connected to the outer cup 384 from an inner side of the gas-liquid separation plate 389.

The controller 600 controls the liquid treating chamber 380 to treat the substrate. In one example, the controller 600 controls the spin chuck 386, the treatment solution supply unit 387, and the nozzle unit 400.

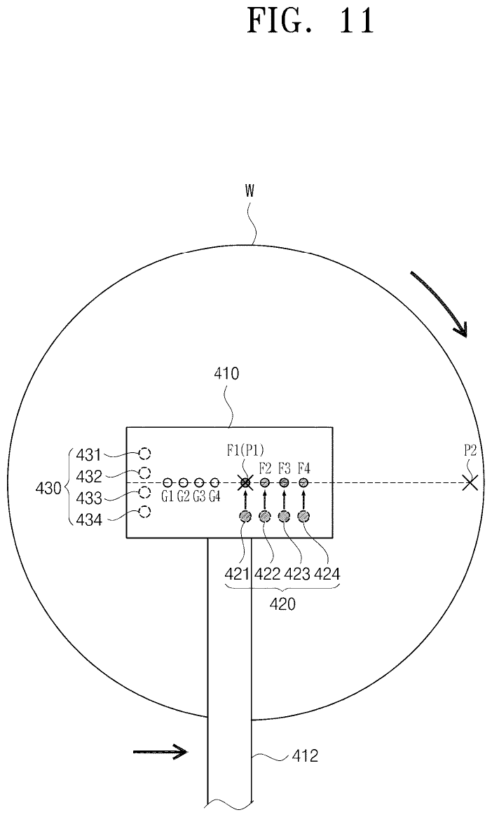

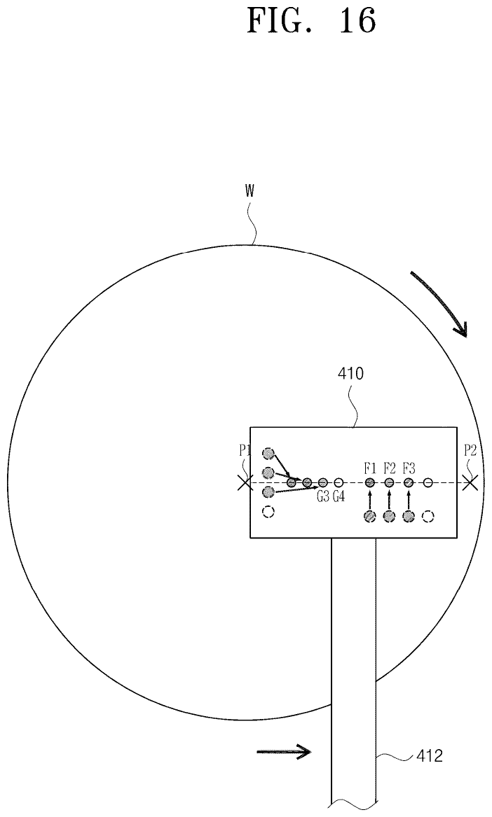

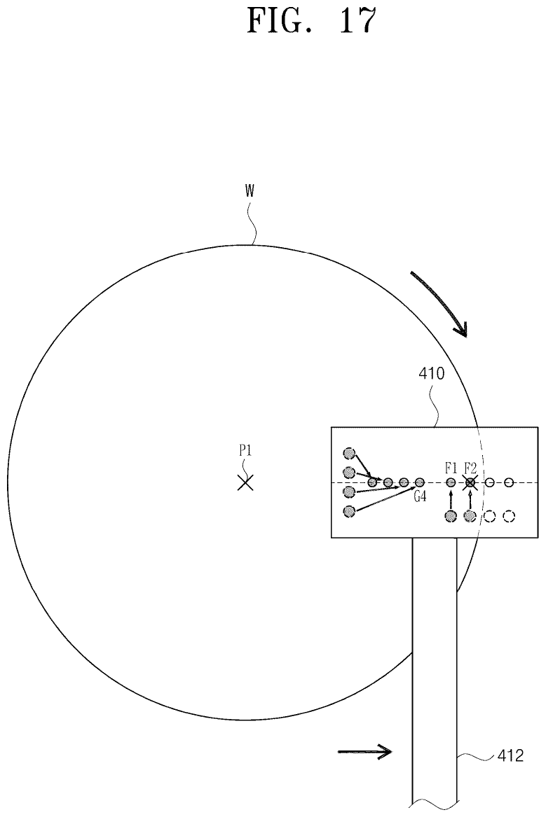

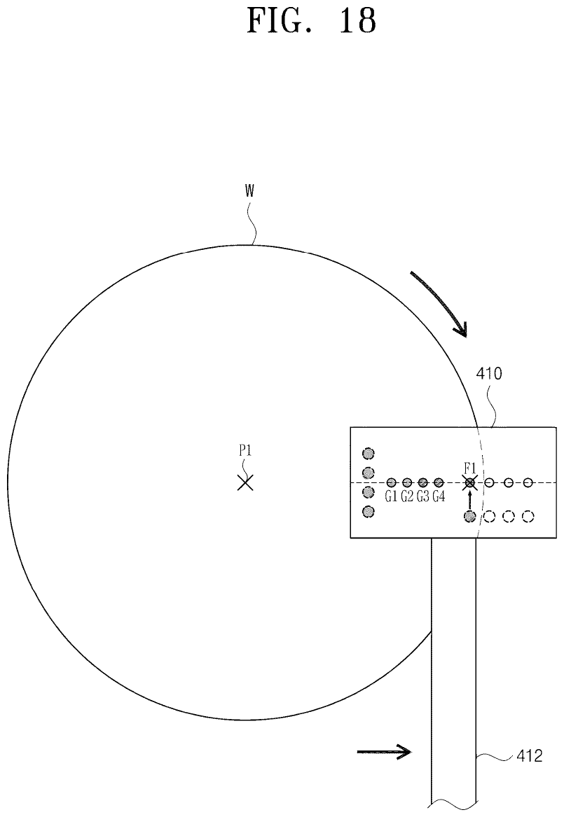

FIGS. 11 to 19 are diagrams schematically illustrating the processes of treating a substrate by using a nozzle unit in the liquid treating chamber of FIG. 8.

Referring to FIGS. 11 to 19, the exemplary embodiment of a process for treating a substrate W in the liquid treating chamber 380 will be described. In the following, the impact points F1, F2, F3, and F4 of the cleaning solution and the impact points G1, G2, G3, and G4 of the drying gas are schematically illustrated, and the nozzles through which the cleaning solution or drying gas is discharged and the impact points of the discharged cleaning solution or drying gas are shown by means of hatching.

The substrate W is loaded into the liquid treating chamber 380 by the transfer robot 351 described above and placed on the spin chuck 386.

The spin chuck 386 rotates, and developer is discharged from the treatment solution supply unit 387 onto the rotating substrate W, so that the resist film on the surface of the substrate W is selectively dissolved.

When the developer supply is terminated, a cleaning process is performed to remove the developer and particles on the substrate W.

In the cleaning process, the head 410 moves to the first position P1, as shown in FIG. 11.

In the portion above the substrate W rotating at a predetermined rotational speed, the head 410 moves in a straight line from the first position P1 to the second position P2 to supply the cleaning solution and drying gas onto the substrate W. When the head 410 is in the first position P1, the cleaning nozzles 421, 422, 423, and 424 discharge the cleaning solution to the cleaning solution impact points F1, F2, F3, and F4, respectively. The first position P1 is the position when the head 410 is in the center region of the substrate W when viewed from above. When the head 410 is in the first position P1, it means that the impact point F1 of the cleaning solution discharged by the first cleaning nozzle 421 coincides with the center of the substrate W.

FIG. 11 illustrates the head 410 and the impact points F1, F2, F3, and F4 of the cleaning solution when the head 410 is in the first position P1. As the cleaning nozzles 421, 422, 423, and 424 discharge the cleaning solution as described above, the cleaning nozzles 421, 422, 423, and 424 and the cleaning solution impact points F1, F2, F3, and F4 in FIG. 11 are hatched.

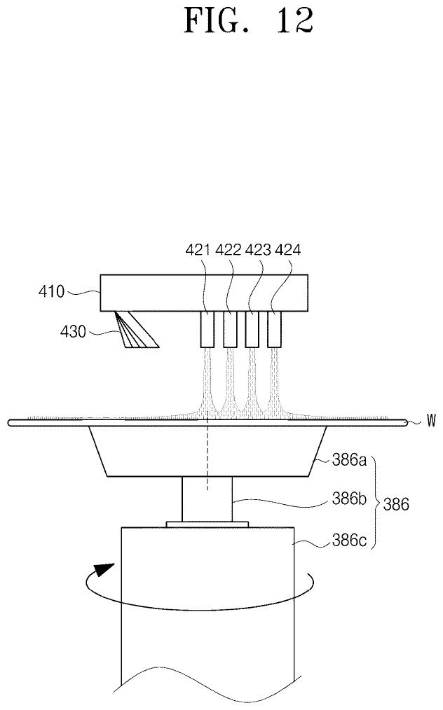

FIG. 12 shows the cleaning nozzles 421, 422, 423, and 424 discharging the cleaning solution onto the substrate W when the head 410 is in the first position P1. As shown in FIG. 12, the cleaning solution discharged onto the substrate W from the first cleaning nozzle 421 is discharged in the center of the substrate W.

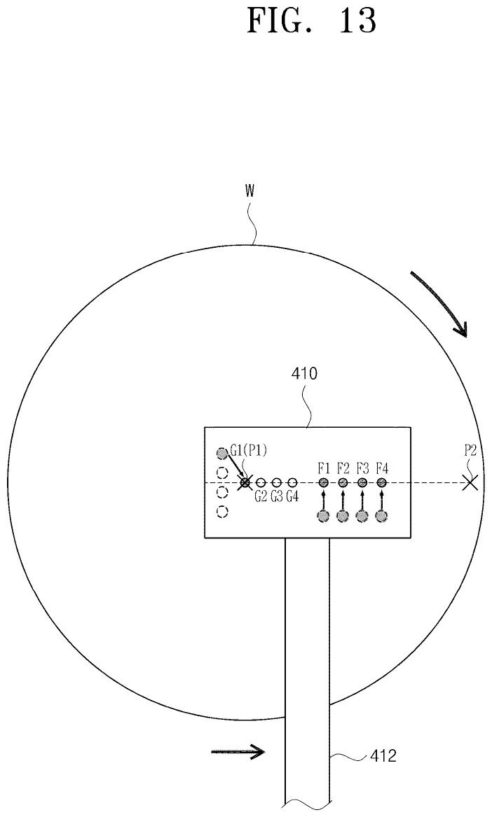

The head 410 then moves in a straight line from the first position P1 to the second position P2, as shown in FIG. 13. At a time when the impact point G1 of the drying gas discharged from the first drying nozzle 431 is located at the center of the substrate W, the drying gas is discharged from the first drying nozzle 431 onto the substrate W.

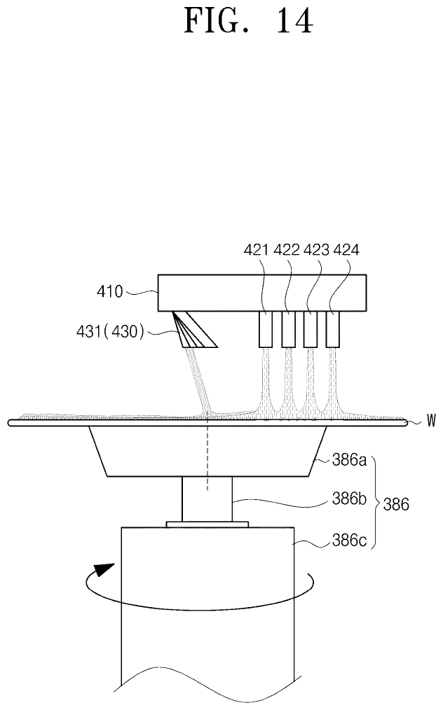

FIG. 14 shows the cleaning nozzles 421, 422, 423, and 424 discharging the cleaning solution onto the substrate W and the first drying nozzle 431 discharging the drying gas onto the substrate W when the drying gas is discharged from the first drying nozzle 431. As shown in FIG. 14, the drying gas discharged onto the substrate W from the first drying nozzle 431 is discharged toward the center of the substrate W.

Depending on the arrangement of the cleaning nozzles 420 and the drying nozzles 430 installed on the head 410 and the direction of movement of the head 410, when the cleaning solution and the drying gas are discharged simultaneously from the head 410, the impact points F1, F2, F3, and F4 of the cleaning solution are located at points farther from the center of the substrate W than the impact points G1, G2, G3, and G4 of the drying gas.

The head 410 continues to move in a straight line from the first position P1 to the second position P2 along the radial direction of the substrate W. As the head 410 moves, the total amount of cleaning solution discharged from the first to fourth cleaning nozzles 421, 422, 423, and 424 decreases and the total amount of drying gas discharged from the first to fourth drying nozzles 431, 432, 433, and 434 increases. For example, as the head 410 moves from the first position P1 to the second position P2, the number of cleaning nozzles discharging the cleaning solution decreases and the number of drying nozzles discharging the drying gas increases.

Among the first to fourth cleaning nozzles 421, 422, 423, and 424, the discharge of the cleaning solution onto the substrate W is stopped sequentially starting from the cleaning nozzle whose impact point of the cleaning solution discharged onto the substrate W is far from the center portion of the substrate W. Among the first to fourth drying nozzles 431, 432, 433, and 434, the discharge of the drying gas onto the substrate W sequentially starts from the drying nozzle whose impact point of the drying gas discharged onto the substrate W is closer to the center portion of the substrate W. Accordingly, as the head 410 moves from the center portion of the substrate W to the edge region of the substrate W, the discharge region of the cleaning solution and the discharge region of the drying gas become closer.

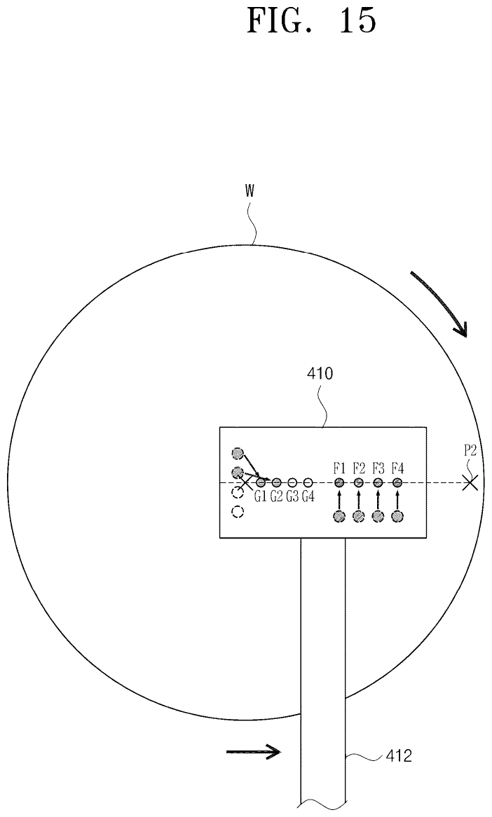

FIGS. 15 to 19 illustrate that, as the head 410 moves, the discharge of the cleaning solution sequentially stop from the cleaning nozzle where the impact point of the cleaning solution is farther from the center portion of the substrate W. That is, the fourth cleaning nozzle 424, the third cleaning nozzle 423, the second cleaning nozzle 422, and the first cleaning nozzle 421 stop discharging the cleaning solution in that order.

FIGS. 15 to 19 illustrate that, as the head 410 moves, the discharge of the drying gas sequentially stop from the drying nozzle where the impact point of the drying gas is closer to the center portion of the substrate W. That is, the first drying nozzle 431, the second drying nozzle 432, the third drying nozzle 433, and the fourth drying nozzle 434 start discharging the drying gas in that order.

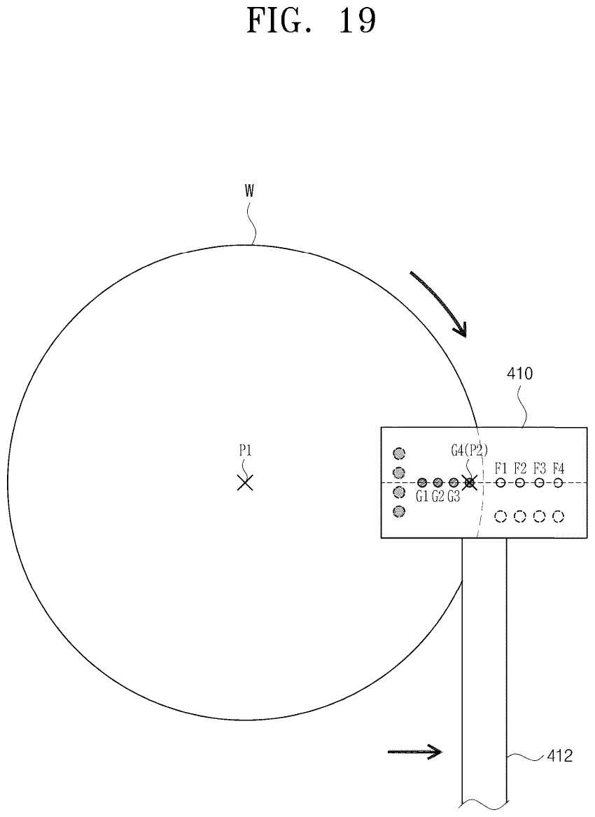

FIG. 19 illustrates a view of the head 410 located in the second position P2. The second position P2 is the position when the head 410 is in the edge region of the substrate W when viewed from above. When the head 410 is in the second position P2, it means that the impact point G4 of the drying gas discharged by the fourth drying nozzle 434 coincides with the second position P2 in the edge region of the substrate W.

When the head 410 completes the movement to the second position P2, the drying gas is discharged to the edge region of the substrate W, and the cleaning and drying treatments of the substrate are terminated.

The nozzle unit 400 of the present invention includes a plurality of cleaning nozzles 420 and a plurality of drying nozzles 430, thereby supplying a large flow rate of cleaning solution or drying gas compared to a single nozzle configuration. When the cleaning nozzle 420 or the drying nozzle 430 each include a single nozzle, it is necessary to enlarge the nozzle diameter or increase the discharge pressure in order to deliver a large flow rate of cleaning solution or drying gas onto the substrate W. However, when the discharge pressure of the cleaning solution or drying gas is increased, the substrate W may be damaged, and particles are residual on the substrate W due to the generation of bubbles.

The nozzle unit 400 according to the exemplary embodiment of the present invention includes the plurality of cleaning nozzles 420 and the plurality of drying nozzles 430, thereby supplying a large flow rate of cleaning solution or drying gas compared to a single nozzle.

The nozzle unit 400 according to the exemplary embodiment of the present invention may reduce the discharge pressure of the cleaning solution or drying gas discharged from each nozzle included in the nozzle unit 400, and may minimize damage to the substrate W or residual particles on the substrate W due to the cleaning solution or drying gas discharged onto the substrate W.

The nozzle unit 400 according to the exemplary embodiment of the present invention may efficiently treat the substrate by freely adjusting the discharge flow rate of the cleaning solution and the drying gas through the plurality of cleaning nozzles 420 and the plurality of drying nozzles 430.

Also, as described above, as the head 410 moves from the center portion of the substrate W to the edge region of the substrate W, the discharge region of the cleaning solution and the discharge region of the drying gas become closer, so it is possible to quickly dry the cleaning solution using the discharged drying gas.

The nozzle unit 400 according to the exemplary embodiment of the present invention may adjust the cleaning speed, the drying speed, and the process speed by adjusting the ratio of the total amount of cleaning solution discharged onto the substrate W to the total amount of drying gas discharged onto the substrate W. In the example described above, as the head 410 moves toward the edge region of the substrate W, the total amount of cleaning solution discharged decreases and the total amount of drying gas discharged increases. As the amount of drying gas relative to the cleaning solution discharged increases as the head 410 moves toward the edge region of the substrate W, the liquid surface of the drying gas may grow rapidly and the substrate W may be dried quickly.

Furthermore, the substrate W may be dried quickly through the drying gas without relying on drying by rotation of the substrate W.

The interface module 500 connects the treating module 300 with an external exposure device 700. The interface module 500 includes an interface frame 501, a buffer unit 510, a cooling unit 520, a transfer mechanism 530, an interface robot 540, and an additional process chamber 560.

The top end of the interface frame 501 may be provided with a fan filter unit forming a downward airflow therein. The buffer unit 510, the cooling unit 520, the transfer mechanism 530, the interface robot 540, and the additional process chamber 560 are disposed inside the interface frame 501.

The structure and arrangement of the buffer unit 510 and the cooling unit 520 may be the same or similar to those of the buffer unit 310 and the cooling unit 320 provided in the treating module 300. The buffer unit 510 and the cooling unit 520 are disposed adjacent to the end of the transfer chamber 350. The substrate W transferred between the treating module 300, the cooling unit 520, the additional process chamber 560, and the exposure device 700 may temporarily stay in the buffer unit 510. The cooling unit 520 may only be provided at a height corresponding to the applying block 300a between the applying block 300a and the developing block 300b.

The transfer mechanism 530 may transfer the substrate W between the buffer units 510. The transfer mechanism 530 may also transfer the substrate W between the buffer unit 510 and the cooling unit 520. The transfer mechanism 530 may be provided with the same or similar structure as the transfer mechanism 330 of the treating module 300. Another transfer mechanism 531 may be further provided in a region opposite the region where the transfer mechanism 530 is provided with respect to the buffer unit 510.

The interface robot 540 is disposed between the buffer unit 510 and the exposure device 700. The interface robot 540 is provided to transfer the substrate W between the buffer unit 510, the cooling unit 520, the additional process chamber 560, and the exposure unit 700. The interface robot 540 has a hand 542 on which the substrate W is placed, and the hand 542 may be provided to be movable forwardly and backwardly, rotatable about an axis parallel to the third direction 16, and movable along the third direction 16.

The additional treating chamber 560 may perform a predetermined additional process before the substrate W, which has been completely processed in the applying block 300a, is loaded into the exposure device 700. Optionally, the additional treating chamber 420 may perform a predetermined additional process before the substrate W, which has been completely processed in the exposure device 700, is loaded into the developing block 300b. In one example, the additional process may be an edge exposure process that exposes an edge region of the substrate W, or a top surface cleaning process that cleans the top surface of the substrate W, or a bottom surface cleaning process that cleans the bottom surface of the substrate W, or an inspection process that performs a predetermined inspection on the substrate W. A plurality of additional process chambers 560 is provided, and may be provided to be stacked on each other.

The example above illustrates the case where the treatment solution is a developer. In contrast, however, the treatment solution may be an acid or base-based chemical.

In the examples described above, the cleaning nozzles 420 and the drying nozzles 430 are described as being provided on the head 410 in a number of four each. However, the cleaning nozzles 420 and the drying nozzles 430 may be provided in various configurations, such as two, three, five or more of each.

In the examples described above, the cleaning nozzles 420 and the drying nozzles 430 are described as being provided in equal numbers on the head 410. However, the plurality of cleaning nozzles 420 and the plurality of drying nozzles 430 may be provided, but in different numbers.

In the examples described above, it has been described that the flow rate is changed depending on the number of cleaning nozzles 420 and drying nozzles 430, but the discharge flow rate may also be changed by varying the nozzle diameter of each of the cleaning nozzles 420 and drying nozzles 430.

In the example described above, it has been described that the head 410 being in the first position P1 means that the impact point F1 of the cleaning solution discharged by the first cleaning nozzle 421 coincides with the center of the substrate W, and the head 410 being in the second position P2 means that the impact point G4 of the drying gas discharged by the fourth drying nozzle 434 coincides with the second position P2 in the edge region of the substrate W. In contrast to this, however, the first position P1 may be a point in the center region of the substrate where the head 410 is located at the time of initiating the substrate W treatment via the nozzle unit 400, and the second position P2 may be a point in the edge region of the substrate where the head 410 is located at the time of terminating the substrate W treatment via the nozzle unit 400.

In the example described above, it has been described that the time point at which the number of cleaning nozzles 420 discharging the cleaning solution is reduced is the same as the time point at which the number of drying nozzles 430 discharging the drying gas is increased. However, in contrast, the time point at which the number of cleaning nozzles 420 discharging the cleaning solution is reduced and the point at which the number of drying nozzles 430 discharging the drying gas is increased may be different.

In the examples described above, it has been described as the cleaning nozzles 420 and the drying nozzles 430 are provided on the single head 410. However, the cleaning nozzles 420 and the drying nozzles 430 may be provided on different heads, and the head on which the cleaning nozzles 420 are provided and the head on which the drying nozzles 430 are provided may be moved in synchronization with each other.

In the example described above, the heads 410 are described as being moved in a straight line along the radial direction of the substrate W between the center region and the edge region of the substrate. However, in contrast to this, the head may be moved in a swinging motion between the center region and the edge region of the substrate.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. An apparatus for treating a substrate, the apparatus comprising:
a spin chuck for supporting a substrate and rotatable;
a nozzle unit for supplying a cleaning solution and drying gas onto the substrate supported by the spin chuck; and
a controller for controlling the nozzle unit,
wherein the nozzle unit includes:
a head;
a plurality of cleaning nozzles provided on the head and for discharging the cleaning solution;
a plurality of drying nozzles provided on the head and for discharging the drying gas; and
a driver for moving the head from a first position to a second position,
when the head is in the second position, an impact point of the cleaning solution discharged from the plurality of cleaning nozzles onto the substrate is at a location farther from a center of the substrate than an impact point of the cleaning solution when the head is in the first position,
when the cleaning solution is discharged simultaneously from the plurality of cleaning nozzles, the impact points of the cleaning solution are located at different distances from the center of the substrate,
when the drying gas is discharged simultaneously from the plurality of drying nozzles, the impact points of the drying gas are located at different distances from the center of the substrate, and
when the cleaning solution and the drying gas are discharged simultaneously, the impact point of the cleaning solution is located farther from the center of the substrate than the impact point of the drying gas.

2. The apparatus of claim 1, wherein when the head is in the first position, the cleaning solution is discharged into a center region of the substrate, and
when the head is in the second position, the drying gas is discharged to an edge region of the substrate.

3. The apparatus of claim 1, wherein the driver is provided to move the head in a straight line between the first position and the second position along a radial direction of the substrate supported on the spin chuck, and
the impact points of the cleaning solution discharged from the plurality of cleaning nozzles onto the substrate are located in a straight line.

4. The apparatus of claim 1, wherein the driver is provided to move the head in a straight line between the first position and the second position along a radial direction of the substrate supported on the spin chuck, and
the impact points of the drying gas discharged from the plurality of drying nozzles onto the substrate are located in a straight line.

5. The apparatus of claim 1, wherein the driver is provided to move the head in a straight line between the first position and the second position along a radial direction of the substrate supported on the spin chuck, and
the impact points of the cleaning solution and the drying gas discharged onto the substrate from the plurality of cleaning nozzles and the plurality of drying nozzles are located in a straight line.

6. The apparatus of claim 1, wherein when viewed from above, the plurality of cleaning nozzles are arranged in a direction parallel to a straight line connecting the first position and the second position.

7. The apparatus of claim 1, wherein when viewed from above, the plurality of drying nozzles are arranged in a direction perpendicular to a straight line connecting the first position and the second position.

8. The apparatus of claim 4, wherein the controller controls the cleaning nozzles such that the total amount of cleaning solution discharged from the plurality of cleaning nozzles decreases as the head moves from the first position to the second position.

9. The apparatus of claim 8, wherein the controller controls the number of the cleaning nozzles discharging the cleaning solution to decrease as the head moves from the first position to the second position.

10. The apparatus of claim 9, wherein the controller controls the plurality of cleaning nozzles to sequentially stop discharging the cleaning solution starting with the cleaning nozzle of which an impact point of the cleaning solution discharged onto the substrate is farthest from the center of the substrate among the plurality of cleaning nozzles as the head moves from the first position to the second position.

11. The apparatus of claim 2, wherein the controller controls the drying nozzles such that the total amount of the drying gas discharged from the plurality of drying nozzles increases as the head moves from the first position to the second position.

12. The apparatus of claim 11, wherein the controller controls the number of the drying nozzles discharging the drying gas to increase as the head moves from the first position to the second position.

13. The apparatus of claim 12, wherein the controller controls the plurality of drying nozzles to sequentially initiate discharging the drying gas starting with the drying nozzle of which an impact point of the drying gas discharged onto the substrate is the center of the substrate or is closest to the center of the substrate among the plurality of drying nozzles as the head moves from the first position to the second position.

14-16. (canceled)

17. An apparatus for treating a substrate, the apparatus comprising:
a chamber providing a treatment space therein;
a spin chuck for supporting a substrate within the treatment space and rotatable;
a nozzle unit for supplying a cleaning solution and drying gas onto the substrate supported by the spin chuck; and
a controller for controlling the nozzle unit,
wherein the nozzle unit includes:
a head;
a plurality of cleaning nozzles provided on the head and for discharging the cleaning solution;
a plurality of drying nozzles provided on the head and discharging the drying gas; and
a driver for moving the head in a straight line from a first position to a second position,
when the head is in the second position, an impact point of the cleaning solution discharged from the plurality of cleaning nozzles onto the substrate is at a location farther from a center of the substrate than an impact point of the cleaning solution when the head is in the first position,
when the cleaning solution is discharged simultaneously from the plurality of cleaning nozzles, the impact points of the cleaning solution are located at different distances from the center of the substrate,
when the drying gas is discharged simultaneously from the plurality of drying nozzles, the impact points of the drying gas are located at different distances from the center of the substrate, and
when the cleaning solution and the drying gas are discharged simultaneously, the impact point of the cleaning solution is located farther from the center of the substrate than the impact point of the drying gas, and
the impact points of the cleaning solution and the drying gas discharged onto the substrate from the plurality of cleaning nozzles and the plurality of drying nozzles are located in a straight line.

18. The apparatus of claim 17,
wherein the controller controls the cleaning nozzles and the drying nozzles such that the total amount of cleaning solution discharged from the plurality of cleaning nozzles decreases and the total amount of drying gas discharged from the plurality of drying nozzles increases as the head moves from the first position to the second position.

19. The apparatus of claim 18, wherein the controller controls the plurality of cleaning nozzles to sequentially stop discharging the cleaning solution starting with the cleaning nozzle of which an impact point of the cleaning solution discharged onto the substrate is farthest from the center of the substrate among the plurality of cleaning nozzles as the head moves from the first position to the second position.

20. The apparatus of claim 18, wherein the controller controls the plurality of drying nozzles to sequentially initiate discharging the drying gas starting with the drying nozzle of which an impact point of the drying gas discharged onto the substrate is the center of the substrate or is closest to the center of the substrate among the plurality of drying nozzles as the head moves from the first position to the second position.
